(19) United States
(12) Patent Application Publication
(10) Pub. No.: US 2008/0135884 A1
(43) Pub. Date: Jun. 12, 2008

(54) SOLID-STATE IMAGING DEVICE AND METHOD FOR MANUFACTURING SAME

(76) Inventor: Hideki KORIYAMA, Kurokawa-gun (JP)

Correspondence Address: BIRCH STEWART KOLASCH & BIRCH, PO BOX 747, FALLS CHURCH, VA, 22040-0747, US

(21) Appl. No.: 11/940,193

(22) Filed: Nov. 14, 2007

(30) Foreign Application Priority Data
Nov. 17, 2006 (JP) P2006-311312

(51) Int. Cl. H01L 27/148; H01L 31/18; H01L 21/339

(52) U.S. Cl. 257/233; 438/60; 257/E27.15

(57) ABSTRACT

A solid-state imaging device is provided and includes a photoelectric conversion unit and a charge transfer unit including charge transfer electrodes for transferring charges generated in the photoelectric conversion unit. Each of the charge transfer electrodes includes a first electrode of a first layer conductive film and a second electrode of a second layer conductive film, which are alternately arranged. The upper edge of the first electrode is protected by a canopy-shaped upper insulating film to ensure a distance between the first and second electrodes. In addition, the first and second electrodes are insulated from each other by an inter-electrode insulating film of a side wall insulating film formed by CVD so as to cover the side wall of the first electrode.

### BACKGROUND OF THE INVENTION

1. Field of the Invention

This invention relates to a solid-state imaging device and a method for manufacturing the same, and more particularly to realization of high precision in charge-transfer electrodes of the solid-state imaging device.

2. Description of Related Art

A solid-state imaging device using CCDs employed for an area sensor includes a photoelectric conversion unit constructed of e.g. photo-diodes and a charge transfer unit provided with charge transfer electrodes for transferring signal charges from the photoelectric conversion unit. A plurality of charge transfer electrodes are adjacently arranged on a charge transfer path formed on a semiconductor substrate, and are sequentially driven.

In recent years, with development of a high pixel-density of CCDs, the demand for high resolution and high sensitivity in the solid-state imaging device has increased more and more so that an increase in the number of the pixels has advanced to giga pixels or more.

In such a circumstance, in order to ensure the high sensitivity, it is difficult to reduce a light receiving area. As a result, reduction in the area occupied by the charge transfer electrodes is inevitable.

Meanwhile, the inter-electrode insulating film formed between the charge transfer electrodes can be formed thin by oxidation (900 to 950° C.) of an electrode material. However, when the oxide film that is thin and good in quality is tried to be formed, the oxidation temperature must be a high temperature of 900° C. as mentioned above. As a result, impurity diffusion advances on the side of the substrate owing to the thermal history by oxidation. This gives rise to various issues inclusive of deterioration of the transfer efficiency and attenuation of the sensitivity.

Forming the inter-electrode insulating film using thermal oxidation is great barrier to impede the high pixel density and scaling-down (realization of high quality) of the solid-state imaging device.

So, in manufacturing the solid-state imaging device, in order to avoid the high temperature process giving extension of the diffusion length of impurities already injected to prevent deterioration of the charge transfer efficiency and lower the temperature of forming the inter-electrode insulating film, the inventor of this invention proposed the charge transfer electrode with the inter-electrode insulating film formed by CVD (JP-A-2006-100367).

In this method, as shown in FIG. 11A, after first electrodes 3a are patterned, a silicone oxide film is formed thereon by CVD at a substrate temperature of 700° C. to 850° C. Thereafter, by anisotropic etching, the silicone oxide film is patterned so that it is insulated by an inter-electrode insulation film of a side wall insulating film 6 covering the side wall of each first electrode 3a as shown in FIG. 11B. Thus, since the inter-electrode insulating film for the charge transfer electrodes in a single-layer electrode structure, in which a first electrode of a first layer conductive film and a second electrode of a second layer conductive film are alternately arranged, is made of the side wall insulating film formed by CVD, the fine interval can be formed surely in a self-aligned manner. In addition, the high temperature process can be avoided to form the insulating film with high quality, thereby easily manufacturing the solid-state imaging device with high reliability and in a fine structure.

However, in this structure, as shown in FIG. 12, in the anisotropic etching step in forming the side wall, the shoulder of the first electrode 3a is scraped so that sufficient film thickness of the insulating film cannot be assured. For example, an inter-electrode distance a decreases. As a result, the withstand voltage between the first and second electrodes is deteriorated so that the short-circuiting between the electrodes may occur.

### SUMMARY OF THE INVENTION

An object of an illustrative, non-limiting embodiment of the invention is to provide a solid-state imaging device capable of improving the withstand voltage, being formed at a low temperature and easily having a fine structure.

According to an aspect of the invention, there is provided a solid-state imaging device including: a photoelectric conversion unit; and a charge transfer unit including charge transfer electrodes that transfer charges generated in the photoelectric conversion unit, wherein each of the charge transfer electrodes includes: a first electrode of a first layer conductive film, a second electrode of a second layer conductive film, an inter-electrode insulating film of a side wall insulating film that covers a side wall of the first electrode so as to insulate the first electrode from the second electrode, and an upper insulating film overlying the first electrode, wherein at least an upper end of the first electrode located immediately beneath the upper insulating film is recessed so that an peripheral edge of the upper insulating film makes a canopy (in other words, the peripheral edge of the upper insulating film sticks out).

In such a structure, since the upper end of the first electrode is recessed, correspondingly, a larger distance between the first electrode and the second electrode is ensured, thereby avoiding short-circuiting between the electrodes and improving the reliability.

Preferably, the first electrode has a width smaller at an interface with the upper insulating film than that at an interface with a gate insulating film.

In accordance with such a structure, the distance between the electrodes can be ensured more surely.

Preferably, the first electrode is trapezoidal in section.

In accordance with such a structure, the distance between the electrodes can be ensured more surely.

An aspect of the invention can provide the above solid-state imaging device including a photoelectric conversion unit and a charge transfer unit including charge transfer electrodes that transfer charges generated in the photoelectric conversion unit, wherein each of the charge transfer electrodes includes a first electrode of a first layer conductive film and a second electrode of a second layer conductive film, which are alternately arranged, and the first electrode and the second electrode are insulated from each other by an inter-electrode insulating film of a side wall insulating film, so as to cover the side wall of the first electrode, formed by CVD at a substrate temperature of 700° C. to 850° C.

In accordance with such a structure, the inter-electrode insulating film of the charge transfer electrode in a single-layer electrode structure in which the first electrode of a first layer conductive film and the second electrode of a second layer conductive film are alternately arranged is formed of the side wall insulating film formed by CVD. For this reason, a sure and fine interval can be formed in a self-aligned manner. Thus, the insulating film with high quality can be formed at a low temperature so that a reliable and finely-structured solid-state imaging device can be easily manufactured.

In the solid-state imaging device according to an aspect of the invention, the side wall insulating film may be an HTO (high-temperature oxidization) film.

In accordance with such a structure, since the HTO film can be formed at a low temperature and is dense and good in the film quality, the side wall insulating film with high quality can be formed. Now, it is desired that the HTO film is deposited at the substrate temperature of 700° C. to 850° C., and a raw material gas is composed of SiH₄:30 seem and N₂O:1800 sccm at 1.0 Torr in total.

In the solid-state imaging device according to an aspect of the invention, the first layer conductive film and the second layer conductive film are a silicon-base conductive film, respectively.

In accordance with such a structure, these films can be formed in a single layer by CMP or etch-back, thereby permitting the device to be easily processed.

The first layer conductive film and the second layer conductive film may be made of “polymetal”.

In accordance with such a structure, the films can be flattened and are low in resistance so that shunt wiring is not necessary. This realizes low-profiling and high speed of the device. Thus, a scaled-down, high sensitivity and reliable solid-state imaging device can be manufactured.

An aspect of the invention is particularly useful in manufacturing a finely-structured solid-state imaging device in which the inter-electrode distance between the first electrode and the second electrode is 0.1 μm or less.

If the inter-electrode distance is 0.1 μm or less, it is difficult to add the insulating film. However, in accordance with an aspect of the invention, the insulating film can be easily formed by leaving the side wall through anisotropic etching of the CVD oxide film. Thus, a fine pattern can be easily formed.

Further, according to an aspect of the invention, there is provided a method for manufacturing a solid-state imaging device, the solid imaging device including a photoelectric conversion unit and a charge transfer unit including charge transfer electrodes that transfers charges generated in the photoelectric conversion unit, the method comprising a process for forming the charge transfer electrodes, which includes: forming first electrodes by depositing a first layer conductive film, covering the first layer conductive film with an upper insulating film, and patterning the first layer conductive film by photolithography so that an upper edge of the first layer conductive film is recessed from the upper insulating film; depositing an insulating film on the first electrodes; forming a side wall insulating film on a side wall of each of the first electrodes by anisotropic etching of the insulating film; forming a second electrode by forming a second layer conductive film on the side wall insulating film and flattening the second layer conductive film by removing the second layer conductive film on the first electrodes so that the second layer conductive film is separated into the second electrodes between the first electrodes.

In accordance with such a configuration, since the first electrode is formed so that its upper end is recessed from the upper insulating film, short-circuiting can be prevented.

In the method for manufacturing a solid-state imaging device, the step of forming the first electrodes may be a step of patterning by quasi-anisotropic etching using the upper insulating film as a hard mask.

In accordance with such a configuration, a desired electrode shape can be obtained with good reproducibility.

In the method for manufacturing a solid-state imaging device, the step of forming the first electrodes may include a step of patterning by anisotropic etching using the upper insulating film as a hard mask and a step of isotropic etching after the anisotropic etching.

In accordance with such a configuration, a desired electrode shape can be obtained with good reproducibility.

The method for manufacturing a solid-state imaging device may include, prior to the step of depositing the insulating film, a step of lightly etching the side wall of each of the first electrodes. The quantity of etching is set at 30 nm to 100 nm.

In accordance with such a configuration, a desired electrode shape can be obtained with good reproducibility.

In the method for manufacturing a solid-state imaging device, this the step of depositing the insulating film may be a step of depositing the insulating film on the first electrodes by CVD at a substrate temperature of 700° C. to 850° C.

In accordance with this method, since the side wall insulating film is formed by CVD, the inter-electrode insulating film with high quality can be formed in a self-aligned manner at a low temperature. Thus, the charge transfer electrode in a single-layer structure, which can be easily formed, provides high reliability and can be scaled down, can be easily formed. The temperature of depositing the insulating film serving as the side wall insulating film is desirably 700° C. to 850° C.

In the method for manufacturing a solid-state imaging device according to an aspect of the invention, the step of depositing the insulating film may include a step of forming an HTO film by CVD.

In accordance with this method, a dense and high quality side wall insulating film can be efficiently formed at a low temperature (about 700° C. to 850° C.).

In the method for manufacturing a solid-state imaging device according to an aspect of the invention, the step of forming the first electrodes may include the steps of forming the first layer conductive film, forming a hard mask of the insulating film on the first layer conductive film, and selectively removing the first layer conductive film using the hard mask.

In accordance with this method, the pattern of each of the first electrodes with high precision and reliability can be formed. Further, in flattening the second layer conductive film, the hard mask serves as a removal suppressing layer (stopper layer) for suppressing the removal of the first electrodes so that a flat surface with no reduction of the film can be effectively formed.

In the method for manufacturing a solid-state imaging device according to an aspect of the invention, the hard mask may be a single-layer film of a silicone oxide film and the second layer conductive film may be layered on the hard mask.

In the method for manufacturing a solid-state imaging device according to an aspect of the invention, the hard mask may be a two-layer film including a silicon oxide film and a silicon nitride film, and the second layer conductive film may be layered on the hard mask.

In accordance with this method, in resist ashing, pollution of the first layer conductive film constituting the first electrode can be prevented. Further, in the step of patterning the second layer conductive film, the hard mask preferably acts as a removal suppressing layer for the first electrode and also in forming the side wall insulating film by anisotropic etching after patterning the second layer conductive film, preferably acts as the removal suppressing layer on the first electrode.

In the method for manufacturing a solid-state imaging device according to an aspect of the invention, the flattening step may be a resist etch-back step.

In accordance with this method, the hard mask preferably acts as the removal suppressing layer for the first electrode.

In the method for manufacturing a solid-state imaging device according to an aspect of the invention, the flattening step may be a flattening step by CMP (Chemical Mechanical Polishing).

In accordance with this method, the hard mask preferably acts as the removal suppressing layer for the first electrode.

The method for manufacturing a solid-state imaging device according to an aspect of the invention may further includes the steps of forming a second hard mask on the substrate surface flattened by the flattening step, and patterning the second layer conductive film using the second hard mask as a mask.

In accordance with this method, in patterning the second layer conductive film, the second hard mask preferably acts as the removal suppressing layer.

In the method for manufacturing a solid-state imaging device according to an aspect of the invention, the second hard mask may be a single-layer film of a silicon oxide film.

In the method for manufacturing a solid-state imaging device according to an aspect of the invention, the second hard mask may be a two-layer film including a silicon oxide film and a silicon nitride film.

In accordance with this method, in resist ashing, pollution of the second layer conductive film constituting the second electrodes can be prevented.

The method for manufacturing a solid-state imaging device according to an aspect of the invention may includes a step of forming a silicon oxide film by CVD on the second layer conductive film patterned, and a step of forming a second side wall insulating film on the side wall of the second layer conductive film patterned by anisotropic etching of the silicon oxide film using a silicon nitride film as a stopper.

In accordance with this method, in the step of patterning the second layer conductive film, the hard mask preferably acts as the removal suppressing layer for the second electrodes.

### BRIEF DESCRIPTION OF THE DRAWINGS

The features of the invention will appear more fully upon consideration of the exemplary embodiments of the inventions, which are schematically set forth in the drawings, in which:

FIG. 1 is a sectional view of a solid-state imaging according to a first exemplary embodiment of the invention;

FIG. 2 is a top view of a solid-state imaging according to the first embodiment of the invention;

FIG. 3 is an enlarged view for explaining a solid-state imaging according to an exemplary embodiment of the invention;

FIG. 4 is a view showing a process for manufacturing a solid-state imaging according to the first embodiment of this invention;

FIG. 5 is a view showing a process for manufacturing a solid-state imaging according to the first embodiment of this invention;

FIG. 6 is a view showing a process for manufacturing a solid-state imaging according to the first embodiment of this invention;

FIG. 7 is a view showing a process for manufacturing a solid-state imaging according to the first embodiment of this invention;

FIG. 8 is a view showing a process for manufacturing a solid-state imaging according to the first embodiment of this invention;

FIG. 9 is a view showing a process for manufacturing a solid-state imaging according to the first embodiment of this invention;

FIG. 10 is a view showing a process for manufacturing a solid-state imaging according to a second exemplary embodiment of this invention;

FIG. 11 is a view for explaining the step of forming a first electrode in the solid-state imaging device in the background art; and

FIG. 12 is a view showing a solid-state imaging device in the background art,

wherein reference numerals in the drawings are set forth below.
1 Si substrate
2 gate oxide film
3a first layer conductive film
3b second layer conductive film
5 HTO film (upper insulating film, hard mask)
6 HTO film
7 HTO film (second hard mask)
9 Si nitride film (second hard mask)
30 photodiode region
50 color filter
60 microlens
70 intermediate layer

### DETAILED DESCRIPTION OF THE EXEMPLARY EMBODIMENTS

According to an exemplary embodiment of the invention, in each of the charge transfer electrodes in which the first electrode of the first layer conductive film and the second electrode of the second layer conductive film are arranged through the inter-electrode insulating film, the upper edge of the first electrode is removed by quasi-anisotropic etching or isotropic etching after anisotropic etching so that the upper insulating film overlies the first electrode so as to make a canopy. For this reason, the short-circuiting between the first electrode and the second electrode can be prevented. Further, since the inter-electrode insulating film is formed of the side wall insulating film which is the oxide film formed on the side wall of the first electrode by CVD, the solid-state imaging device which can be formed at a low temperature, and is fine, precise and reliable can be manufactured.

Now referring to the drawings, an explanation will be given of various exemplary embodiments of the invention.

### Embodiment 1

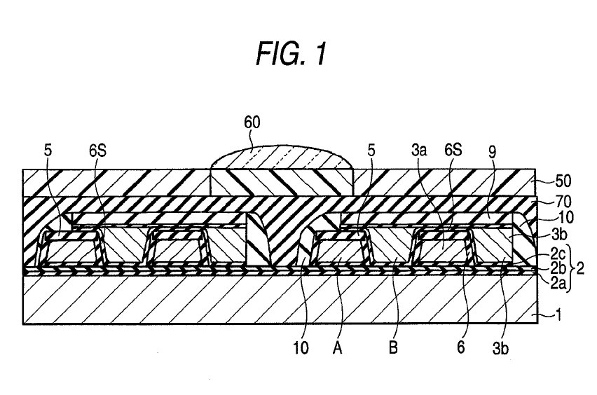

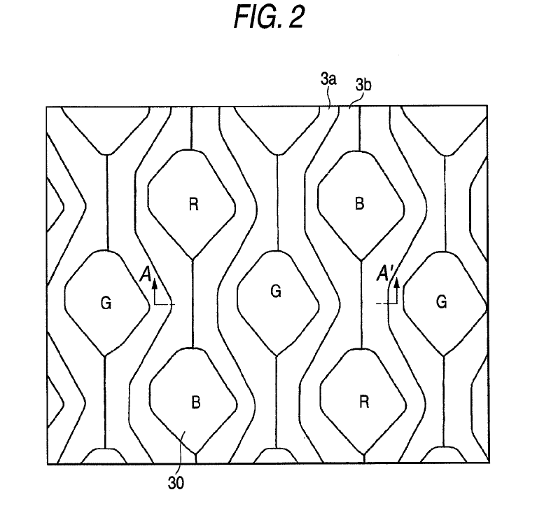

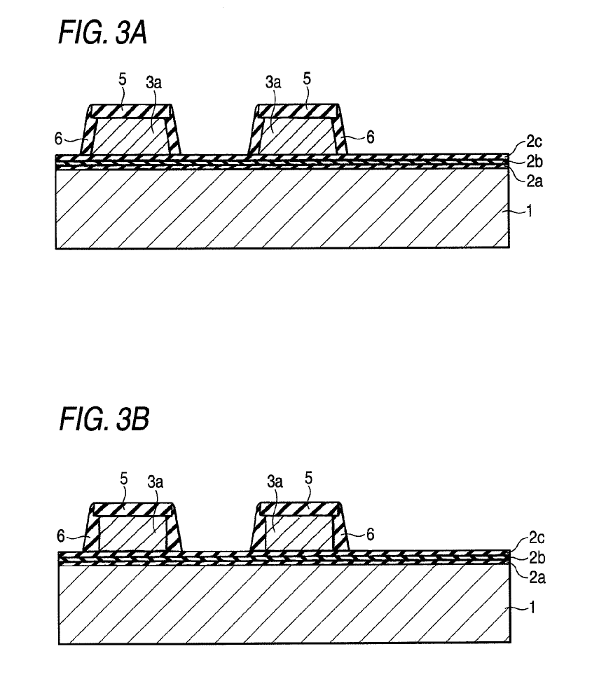

A solid-state imaging device, as shown in FIGS. 1 and 2, includes charge-transfer electrodes formed in a single-layer electrode structure in which a first electrode A of a poly-Si layer serving as a first layer conductive film 3a and a second electrode B of a poly-Si layer serving as a second layer conductive film 3b are alternately arranged, the upper edge of the first electrode A is covered with an upper insulating film 5 having a canopy shape by quasi-anisotropic etching thereby to assure a distance between the first electrode and second electrode and so prevent the short-circuiting, and an inter-electrode insulating film is made of a side wall insulating film 6 of an HTO film formed by CVD. FIG. 3A is an enlarged view of the main part of the first electrode.

In accordance with the above structure, the upper edge of the first electrode A is removed by quasi-anisotropic etching so as to be covered with an upper insulating film having a canopy shape thereby to assure a distance between the first electrode and second electrode and so prevent the short-circuiting. Further, the inter-electrode insulating film is constructed of the side wall insulating film of an HTO film formed by CVD so that the side wall insulating film with high quality can be formed at low temperatures. The extension of the diffusion length can be also suppressed. Thus, the single-layer electrode structure with the first electrode A and second electrode B alternately arranged and a flat surface can be easily formed.

The remaining structure, which is the same as in an ordinary solid-state imaging device, includes photoelectric conversion units 30, a charge transfer unit (not shown) with the charge transfer electrodes for transferring charges generated in the photoelectric conversion unit 30. The structure further includes an intermediate layer 70 which includes a light-shielding film (not shown) formed to have an opening in the photoelectric conversion unit and a flattened film of a BPSG (borophospho silicate glass) film filled in the photoelectric conversion unit so that the surface is nearly flat. This structure further includes a filter 50 and a lens 60 which are formed on the intermediate layer.

In this way, the surface can be preferably flattened so that the structure can be greatly low-profiled.

A gate oxide film 2 is formed of a three-layer structural film including a silicon oxide film 2a, silicon nitride film 2b and silicon oxide film 2c.

FIG. 1 is a schematic sectional view and FIG. 2 is a schematic plan view. FIG. 1 is a sectional view taken in line A-A in FIG. 2. On a silicon substrate 1, a plurality of photo-diode areas 30 are formed. A charge-transfer unit for transferring signal charges detected by the photo-diode regions 30 is formed among the photo-diode regions 30.

Charge transfer channels along which signal charges transferred by the charge transfer electrodes, although not shown in FIG. 2, are formed in a direction crossing the direction in which the charge transfer unit 40 is extended.

It should be noted that among the inter-electrode insulating films, the film formed in the vicinity of the boundary between the photo-diode area 30 and the charge transfer unit is not illustrated in FIG. 2.

Further, as shown in FIG. 1, within the silicon substrate 1, the photo-diode areas 30, charge transfer channels (not shown), channel stop areas (not shown) and charge read-out areas (not shown) are formed. On the surface of the silicon substrate 1, the gate oxide film 2 is formed. On the surface of the gate oxide film 2, the charge transfer electrode (including the first electrode A of the first layer conductive film 3a and the second electrode B of the second layer conductive film 3b) and the inter-electrode insulating film 6 serving as the side wall insulating film of the HTO film (silicon oxide film) formed on the side wall of the first electrode A are formed so that they are arranged, thereby constituting the single-layer electrode structure.

The charge transfer unit is formed as described above. As shown in FIG. 1, on the charge transfer electrodes of the charge transfer unit, the intermediate layer 70 is formed. Further, except the photo-diode areas 30 (photo-converting unit), a light-shielding film (not shown) and an anti-reflective layer of a silicon nitride film are formed. On the concave area, a flattened film of a BPSG film is formed. On the flattened film, a passivation film of a transparent film is formed.

Above the intermediate layer 70, a color filter 50 and a microlens 60 are formed. Between the color filter 50 and the microlens 60, a flattened layer of insulating transparent resin or the like may be filled as the occasion demands.

Further, in the embodiment, the solid-state imaging device having a honeycomb structure is shown, but it is needless to say that the invention can be applied to a solid-state imaging device of a square-lattice type.

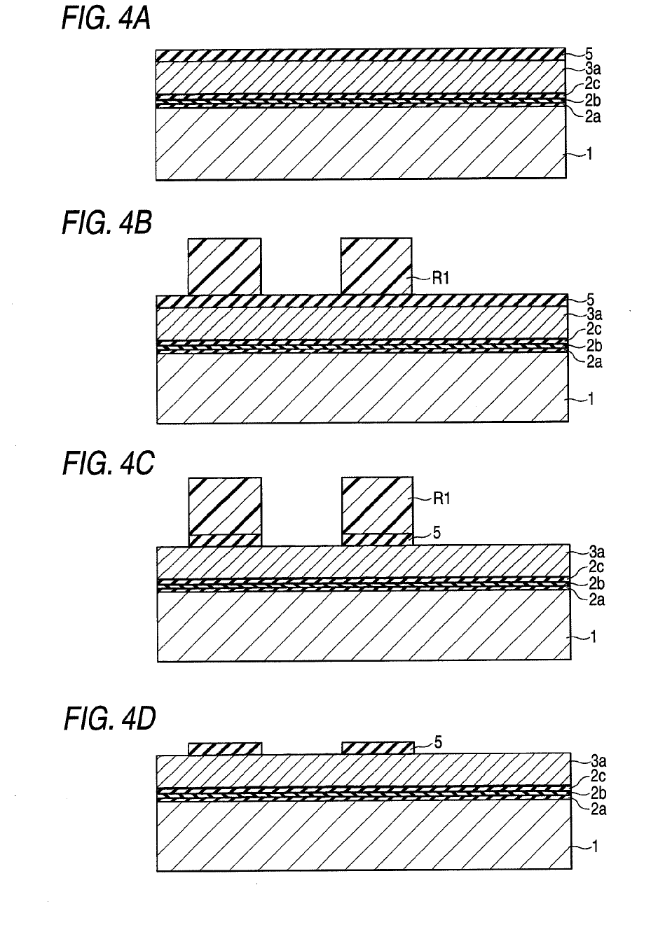

Next, referring to FIGS. 4 to 9, a detailed explanation will be given of a manufacturing process of the solid-state imaging device.

First, on the surface of an n-type silicon substrate 1 with an impurity concentration of above 1.0×10¹⁶ cm⁻³, a silicon oxide film 2a having a thickness of 15 nm, a silicon nitride film 2b having a thickness of 50 nm and a silicon oxide film 2c having a thickness of 10 nm are formed, thereby forming a gate oxide film 2 in a three-layer structure.

Subsequently, on the gate oxide film 2, by reduced-pressure CVD, a first layer polysilicon film having a thickness of 50 to 300 nm serving as a first layer conductive film 3a is formed. The substrate temperature at this time is set at 500 to 600 C°. Sequentially, on this film, an HTO film 5 having a thickness of 50 to 300 nm is formed at the substrate temperature of 850 C° (700 to 850 C°) is formed by the CVD (FIG. 4A).

Thereafter, by photolithography, a first resist pattern R1 is formed (FIG. 4B).

The HTO film 5 is etched by reactive ion etching using CHF₃, C₂F₆, O₂ and He (FIG. 4C) and the resist pattern R1 is removed by ashing to form a hard mask (FIG. 4D).

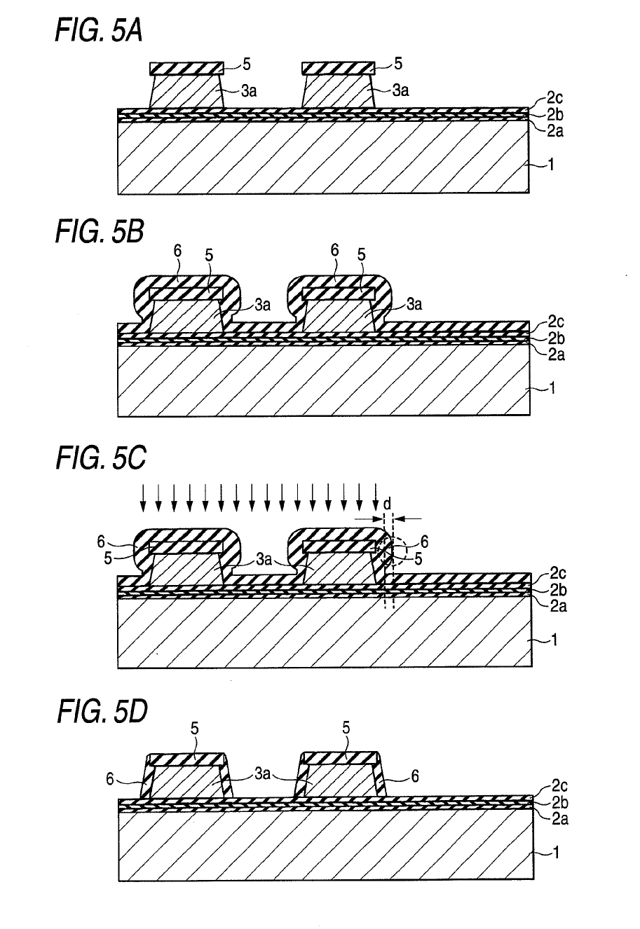

Using the hard mask of the HTO film 5 thus acquired, the first layer conductive film 3a is etched (FIG. 5A). In this etching, using a mixed gas of HBr and O₂, reactive ion etching with RF power of 50 W or more is performed to form a first electrode and wirings of a peripheral circuit thereof. The etching condition was set at HBr+O₂ of 3 to 6%, RF of 50 W or more, and 0.6 to 2.0 Pa.

In this case, it is desirable to use ECR (Electron Cyclotron Resonance) system or ICP (Inductively Coupled Plasma). In the solid-state imaging device after completed, the HTO film 5 serves as an upper insulating film.

Thereafter, by reduced-pressure CVD, an HTO (silicon oxide) film 6 having a thickness of 50 to 300 nm is formed (FIG. 5B).

By reactive ion etching, the silicon oxide film 6 deposited on the horizontal area is removed so that it remains on the side wall to create a “side wall” (insulating film) (FIG. 5C). In this case, in order to reduce the damage of the substrate surface due to the reactive ion etching, a slight quantity (about 25 to 50 nm) of the silicon oxide film 6 is also left on the horizontal area. It is desirable to set the quantity of projection d at 100 nm or less. This value considers the limit to be etched due to diffraction of the reactive ion etching.

Subsequently, by wet etching, the silicon oxide film remaining on the horizontal area is removed (FIG. 5D). At this time, even if the first electrode is tapered, since the oxide film is tapered owing to the shape of the first electrode, the oxide film on the lower side is not prone to be scraped, thereby assuring the film thickness.

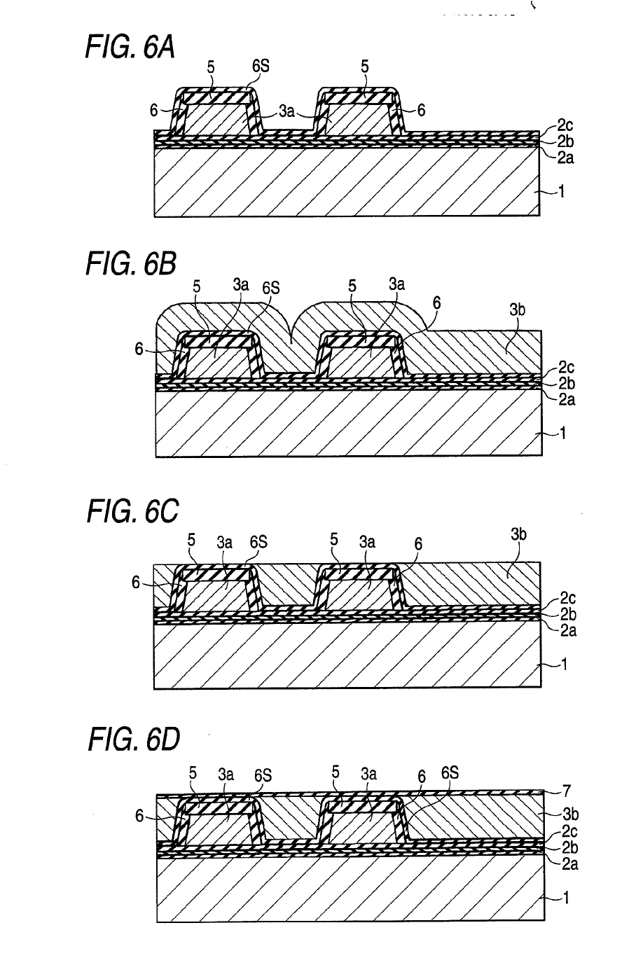

Thereafter, by reduced CVD, an HTO film 6S is formed to supplement the HTO film removed by wet etching, thereby forming the HTO (silicone oxide) film 6S having a thickness of 3 to 10 nm serving as the top oxide film of an ONO film (FIG. 6A).

Subsequently, by reduced CVD, a polysilicon film serving as the second layer conductive film 3b is formed on the film 6S so that it is not lower than the first layer conductive film 3a. The substrate temperature at this time is set at 500 to 600° C. (FIG. 6B).

Further, by CPM (Chemical Mechanical Polishing), the projection of the second layer conductive film 3b is removed to flatten the surface (FIG. 6B).

Further, by reduced pressure CVD, an HTO film 7 having a thickness of 50 nm or less is formed (FIG. 6D).

The second electrode (second layer conductive film) is patterned to open a window of the photoelectric conversion unit.

First, like the patterning of the first electrode, by reduced CVD, a silicon nitride film 9 having a thickness of 50 nm or less is formed to form a hard mask.

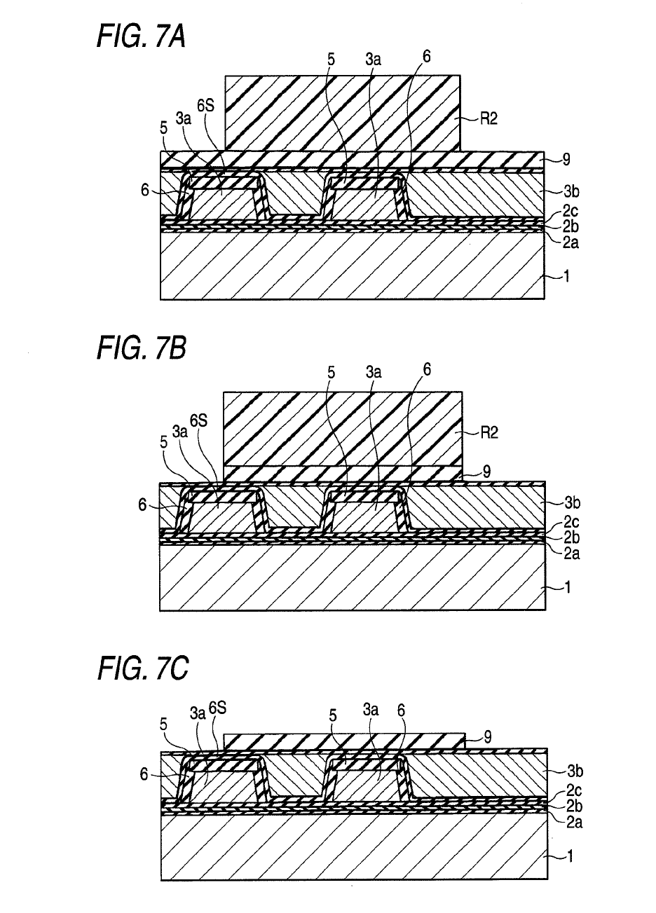

Thereafter, by photolithography, a second resist pattern R2 is formed (FIG. 7A).

By reactive ion etching using CHF₃, CF₄ and Ar, the silicon nitride film 9 is etched (FIG. 7B), and by ashing, the resist pattern R2 is removed to form a hard mask (FIG. 7C).

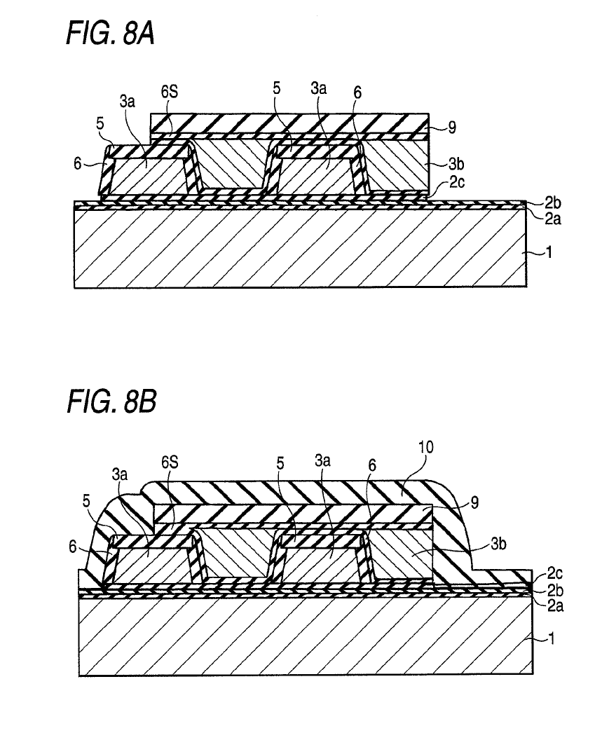

By reactive ion etching using CHF₃, CF₄ and Ar using the silicon nitride film 9 as a mask, the HTO film 7 is patterned. Using the hard mask (second hard mask) composed of the HTO film 7 thus acquired and the silicon nitride film 9, the polysilicon film serving as the second layer conductive film 3b is etched (FIG. 8A). In this etching, reactive ion etching using a mixed gas composed of HBr and O₂ or Cl₂ and O₂ is done to form a window in the photoelectric conversion unit. In this case, it is desirable to employ the etching apparatus such as ECR or ICP. Since the hard mask is used, pollution of the electrode material (second layer conductive film) can be avoided.

Further, an HTO (silicon oxide) film 10 having a thickness of 500 nm is formed (FIG. 5B).

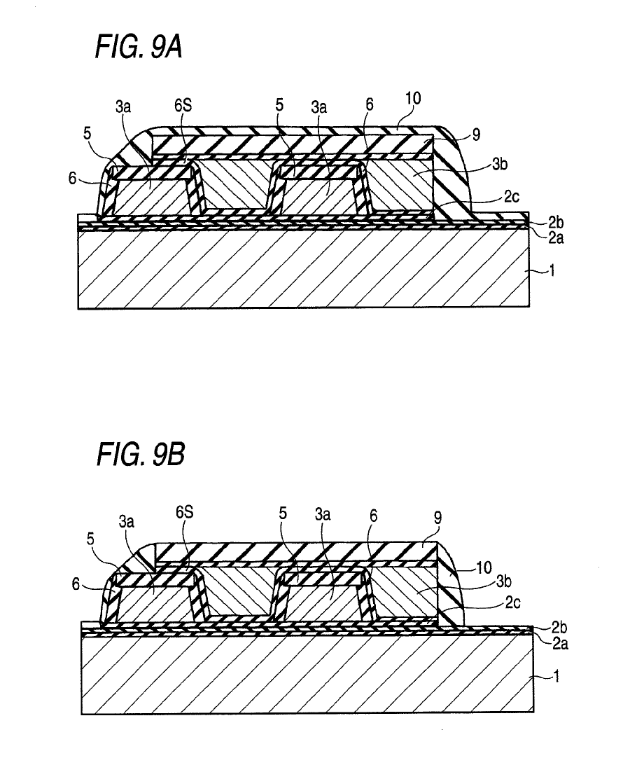

By reactive ion etching, the HTO film 10 deposited on the horizontal area is removed so that it remains on the side wall to create a side wall insulating film (FIG. 9A). In this case, in order to reduce the damage of the substrate surface due to the reactive ion etching, a slight quantity of the HTO film 10 is also left on the horizontal area.

Subsequently, by wet etching, the HTO film 10 left on the horizontal area is removed (FIG. 9B).

Thus, the charge transfer electrode having low resistance is formed.

The anti-reflective film and the intermediate layer 70 such as a light-shielding layer and a flattened film are formed. The color filter 50, microlens 60 and the like are further formed. Thus, the solid-state imaging device as shown in FIGS. 1 and 2 is completed.

In accordance with the solid-state imaging device thus completed, the charge transfer electrode includes the first electrode of the first layer conductive film 3a of a polysilicon layer and the second electrode of the second electrode of the second layer conductive layer 3a of the polysilicon layer, which are alternately arranged through the side wall of the HTO film 6 formed by reduced CVD; and the upper edge of the first electrode is located internally of the lower edge thereof so that the upper insulating film constitutes a canopy. For this reason, short-circuiting between the first electrode and the second electrode can be prevented. Further, since the charge transfer electrode is formed in the structure of a single-layer structure electrode having a low resistance at a low temperature, there is no extension of the diffusing length, thereby providing a precise and fine solid-state imaging device and realizing the high speed and scale-down of the device.

In accordance with this method, the scaled-down structure having an inter-electrode distance of about 0.1 μm can be formed.

Since the HTO film serving as a hard mask for patterning and an etching stopper layer is used, the precise and fine pattern can be formed. Further, by using the etching stopper, film reduction due to excessive grinding can be prevented.

### Embodiment 2

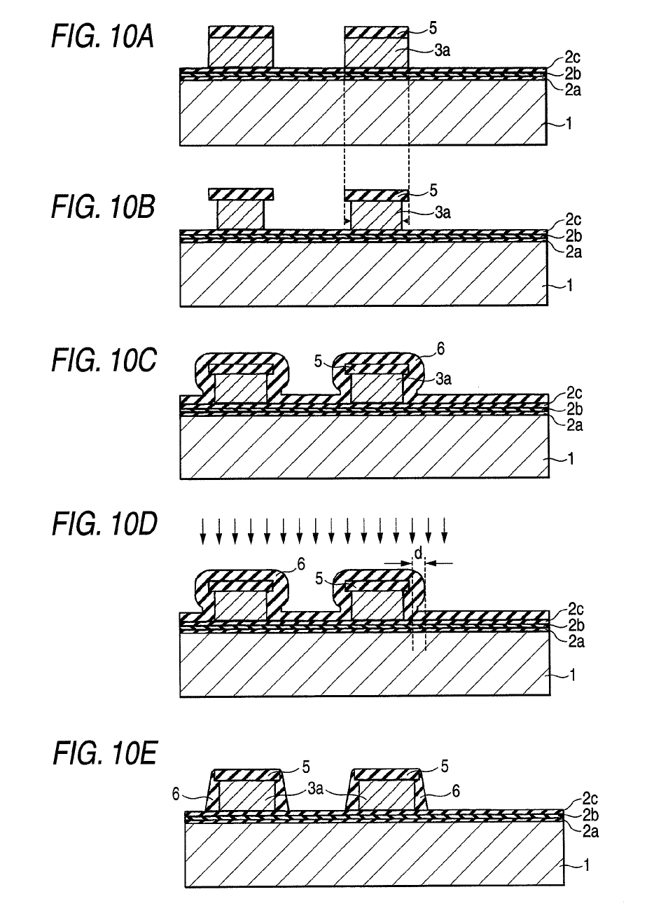

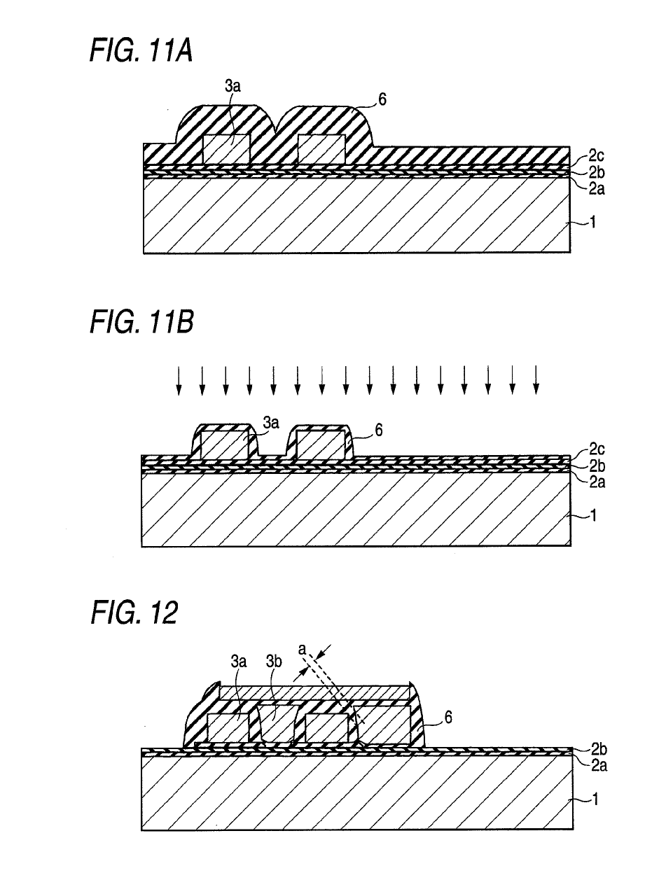

This embodiment is different from the first embodiment in that as shown in FIG. 10B, the shape of the first electrode is structured so that its width is narrower than the upper insulating film 5. In the first embodiment, the first electrode is patterned by quasi-anisotropic etching whereas in this embodiment, it is patterned by isotropic etching after anisotropic etching, thereby providing the above electrode shape. The remaining process is the same as that in the first embodiment.

FIG. 10 shows the steps of forming the first electrode. These steps correspond to those in FIGS. 5A to 5D in the first embodiment. FIG. 5A in the first embodiment corresponds to FIGS. 10A and 10B in this embodiment.

Using the hard mask of the HTO film 5 formed in the steps of FIGS. 4A to 4D, the first layer conductive film 3a is etched (FIG. 10A). In this etching, using the mixed gas of HBr and O₂, reactive ion etching of RF power of 30 W or less is performed to form the first electrode and wirings of a peripheral circuit thereof. In this case, it is desirable that oxygen contained in the etching gas is set at 5% or less.

Subsequently, by chemical dry etching (CDE), the etching is performed by the thickness of about 100 nm. Thus, as shown in FIG. 10B, the first conductive film is etched so that it gives the shape that is square and covered with the insulating film 5 having a canopy shape.

Thereafter, as in the first embodiment, as an overlying layer, an HTO (silicon oxide) film 6 having a thickness of 50 to 300 nm by reduced pressure CVD (FIG. 10C).

By reactive ion etching, the silicon oxide film 6 deposited on the horizontal area is removed so that it remains on the side wall to create a side wall insulating film (FIG. 10D). In this case, in order to reduce the damage of the substrate surface due to the reactive ion etching, a slight quantity (about 25 to 50 nm) of the silicon oxide film 6 is also left on the horizontal area. It is desirable to set the quantity of projection d at 100 nm or less. This value considers the limit to be etched due to diffraction of the reactive ion etching.

Subsequently, by wet etching, the Si oxide film remaining on the horizontal area is removed (FIG. 10E).

The succeeding steps, which are similar to those in first embodiment, will not be explained.

In this way, the first electrode is etched by a two-step etching including anisotropic etching and isotropic etching using the hard mask, the upper edge of the first electrode is removed to make a tapered shape thereby being recessed from the upper insulating film 5 so that the upper insulating film overlies the first electrode to make a canopy. In this structure, the distance between the first electrode and the second electrode can be assured, thereby preventing the short-circuiting therebetween.

Although the remaining structure is the same as that in the first embodiment, the two-layer film may be employed in patterning the second electrode. In this way, by forming the hard mask of the two-layer film, the patterning precision is improved and its reliability is improved as the insulating film. Further, since the two-layer film functions as a removal-preventing layer (etching stopper) in the flattening step serving electrode isolation by CMP or etch-back, the production yield can be further improved.

In the embodiments described above, although the first electrode and second electrode were formed of the polysilicon layer, both electrodes may be formed in a structure in which a metal silicide layer such tungsten silicide is formed on the surface.

In this case, the metal constituting silicide should not be limited to tungsten (W), but may be appropriately changed to titanium (Ti), cobalt (Co) or nickel (Ni). Further, the Si layer should not be limited to poly-Si, but may be appropriately changed to an amorphous Si layer or a microcrystal Si layer.

In the first and second embodiments, the etching was performed using the hard mask. However, it is needless to say that ordinary resist etching may be adopted.

Further, after the step of patterning the first electrode is performed along the ordinary process, before forming the insulating film by CVD, the periphery of the first electrode may be removed by light etching so that upper insulating film overhangs in a canopy shape. Although the etching is performed in a state where the upper face is covered with the mask (upper insulating film), the quantity of etching is desirably about 30 to 100 nm.

Further, without being limited to the embodiments described, the manufacturing method can be appropriately changed.

As understood from the description hitherto made, in accordance with this invention, since the upper edge of the first electrode is removed so that the upper insulating film constitutes a canopy, the inter-electrode distance for the second electrode can be ensured to prevent the short-circuiting. In addition, since the side wall insulating film is formed of the HTO film formed by CVD, a fine and reliable charge transfer electrode in the single-layer electrode structure, thereby permitting low-profiling and reducing the margin for an incident angle of light. So, this charge transfer electrode is useful in manufacturing a fine and high-sensitivity solid-state imaging device such as a small camera.

While the invention has been described with reference to the exemplary embodiments, the technical scope of the invention is not restricted to the description of the exemplary embodiments. It is apparent to the skilled in the art that various changes or improvements can be made. It is apparent from the description of claims that the changed or improved configurations can also be included in the technical scope of the invention.

This application claims foreign priority from Japanese Patent Application No. 2006-311312, filed Nov. 17, 2006, the entire disclosure of which is herein incorporated by reference.

What is claimed is:

1. A solid-state imaging device comprising:
a photoelectric conversion unit; and
a charge transfer unit including charge transfer electrodes that transfer charges generated in the photoelectric conversion unit, wherein each of the charge transfer electrodes includes:
a first electrode of a first layer conductive film,
a second electrode of a second layer conductive film,
an inter-electrode insulating film of a side wall insulating film that covers a side wall of the first electrode so as to insulate the first electrode from the second electrode, and
an upper insulating film overlying the first electrode, wherein at least an upper end of the first electrode located immediately beneath the upper insulating film is recessed so that an peripheral edge of the upper insulating film makes a canopy.

2. The solid-state imaging device according to claim 1, further including a gate insulating film, wherein the first electrode has a width smaller at an interface with the upper insulating film than at an interface with the gate insulating film.

3. The solid-state imaging device according to claim 1, wherein the first electrode is trapezoidal in section.

4. The solid-state imaging device according to claim 1, wherein the side wall insulating film is a CVD film formed at a substrate temperature of 700° C. to 850° C. so as to cover the side wall of the first electrode.

5. The solid-state imaging device according to claim 1, wherein the side wall insulating film is a silicon oxide film around the first electrode, which is formed by lightly oxidizing a periphery of the first electrode.

6. The solid-state imaging device according to claim 4, wherein the side wall insulating film is an HTO film.

7. The solid-state imaging device according to claim 1, wherein said upper insulating film is a silicon nitride film.

8. The solid-state imaging device according to claim 1, wherein each of the first layer conductive film and the second layer conductive film is a silicon conductive film.

9. A method for manufacturing a solid-state imaging device, the solid imaging device including a photoelectric conversion unit and a charge transfer unit including charge transfer electrodes that transfers charges generated in the photoelectric conversion unit,
the method comprising a process for forming the charge transfer electrodes, which includes:
forming first electrodes by depositing a first layer conductive film, covering the first layer conductive film with an upper insulating film, and patterning the first layer conductive film by photolithography so that an upper edge of the first layer conductive film is recessed from the upper insulating film;
depositing an insulating film on the first electrodes;
forming a side wall insulating film on a side wall of each of the first electrodes by anisotropic etching of the insulating film;
forming a second electrode by forming a second layer conductive film on the side wall insulating film and flattening the second layer conductive film by removing the second layer conductive film on the first electrodes so that the second layer conductive film is separated into the second electrodes between the first electrodes.

10. The method according to claim 9, wherein the forming of the first electrodes includes patterning the first layer conductive layer by quasi-anisotropic etching using the upper insulating film as a hard mask.

11. The method according to claim 9, wherein the forming of the first electrodes includes: patterning the first layer conductive layer by anisotropic etching using the upper insulating film as a hard mask; and isotropic etching after the anisotropic etching.

12. The method according to claim 9, wherein the process for forming the charge transfer electrodes further includes etching the side wall of each of the first electrodes by 30 nm to 100 nm, before the depositing of the insulating film

13. The method according to claim 9, wherein the depositing of the insulating film includes depositing the insulating film on the first electrodes by CVD at a substrate temperature of 700° C. to 850° C.

14. The method according to claim 13, wherein the depositing of the insulating film includes forming an HTO film by CVD.

15. The method for manufacturing a solid-state imaging device according to claim 9, wherein the forming of the first electrodes includes forming the first layer conductive film, forming a hard mask of the insulating film on the first layer conductive film, and selectively removing the first layer conductive film using the hard mask.

16. The method according to claim 15, wherein the hard mask is a single-layer film of a silicon oxide film, and the second layer conductive film is layered on the hard mask.

17. The method according to claim 15, wherein the hard mask is a two-layer film including a silicon oxide film and a silicon nitride film, and the second layer conductive film is layered on the hard mask.

18. The method according to claim 9, wherein the flattening of the second layer conductive film is a resist etch-hack process.

19. The method according to claim 9, wherein the flattening of the second layer conductive film is a flattening process by chemical mechanical polishing.

20. The method according to claim 9, wherein the forming of the second electrodes further includes:
forming a second hard mask on a surface flattened by the flattening of the second layer conductive film; and
patterning the second layer conductive film using the second hard mask as a mask.
